(19) United States
(12) Patent Application Publication
(10) Pub. No.: US 2021/0043745 A1
(43) Pub. Date: Feb. 11, 2021

(54) THIN FILM TRANSISTOR ARRAY SUBSTRATE

(71) Applicant: TCL CHINA STAR OPTOELECTRONICS TECHNOLOGY CO., LTD., Shenzhen, Guangdong (CN)

(72) Inventor: Jing LIU, Shenzhen, Guangdong (CN)

(21) Appl. No.: 16/616,468

(22) PCT Filed: Oct. 24, 2019
(86) PCT No.: PCT/CN2019/112990

§ 371 Date: Nov. 24, 2019

(30) Foreign Application Priority Data
Aug. 8, 2019 (CN) 201910729851.2

(51) Int. Cl. H01L 29/49; H01L 27/12; H01L 29/45; H01L 29/786

(52) U.S. Cl. CPC H01L 29/4908; H01L 29/78696; H01L 29/45; H01L 27/124

(57) ABSTRACT

A thin film transistor array substrate, including a substrate, a gate electrode, a gate insulating layer, an active layer, an ohmic contact layer, source/drain electrodes, a pixel electrode, and a passivation layer, which are sequentially disposed; wherein the gate electrode and the source/drain electrodes are a two-layer structure including a molybdenum ternary alloy barrier layer and a copper electrode layer. The problem of undercut and tunneling of a metal layer in the thin film transistor array substrate are solved by the two-layer structure, thereby improving yield of the product.

### FIELD OF INVENTION

The present invention relates to the field of display technologies, and in particular, to a thin film transistor array substrate.

### BACKGROUND OF INVENTION

With advancement of information technology, display screens have gradually developed in the direction of high quality and high functionality. The more functions and the higher picture quality a display screen has, the greater the number of thin film transistors (TFTs) is required. In turn, the more complicated the circuit above the thin film transistor array substrate becomes, and the longer the metal wires for electrical connection gets, which causes a delay in signals. In the manufacturing process of large-sized display panels, metal layout process for electrical connection in the thin film transistor array substrate has replaced aluminum process with copper process since copper has better conductivity and lower impedance.

Generally, a barrier layer having a metal component is coated between copper electrodes and a substrate to increase adhesion of the copper to the substrate and to block diffusion of copper to an active layer of the thin film transistors. Since material properties of molybdenum have low resistivity, good adhesion to substrates, and good barrier to copper diffusion, it is one of the choices of barrier materials. However, molybdenum is susceptible to corrosion in alkaline photoresist stripping solution, resulting in undercuts and undercuts resulting in subsequent copper tunneling.

How to improve the undercut and subsequent tunneling of the metal layer in the thin film transistor array substrate and improve yield of the product correspondingly are urgent problems to be solved.

### Technical Problem

Molybdenum is easily corroded in alkaline photoresist stripping solution, which causes undercut and subsequent tunneling of copper. How to improve the undercut and subsequent tunneling of the metal layer in the thin film transistor array substrate and improve yield of the product correspondingly are urgent problems to be solved.

### SUMMARY OF INVENTION

### Technical Solution

In order to solve the problem of undercut and tunneling of the metal layer in the thin film transistor array substrate, thereby improving the yield of the product, the present invention provides a thin film transistor array substrate including a substrate, a gate, a gate insulating layer, an active layer, an ohmic contact layer, a source/drain, a pixel electrode, and a passivation layer, which are sequentially disposed, wherein the gate and the source/drain are a two-layer structure including a molybdenum ternary alloy barrier layer and a copper electrode layer.

In one embodiment of the invention, the molybdenum ternary alloy barrier layer includes three metal elements, two metal elements thereof are molybdenum and titanium, and the other metal element thereof is selected from one of aluminum, chromium, or nickel.

In one embodiment of the invention, a content of titanium ranges from 0.5% to 85%.

In one embodiment of the invention, a content of aluminum ranges from 0.5% to 85%, a content of chromium content ranges from 0.5% to 85%, and a content of nickel ranges from 0.5% to 85%.

In one embodiment of the invention, a projected area of the ohmic contact layer on the substrate is greater than or equal to a projected area of the source/drain on the substrate.

In one embodiment of the invention, the active layer further includes a thin film transistor channel region, the ohmic contact layer has a portion extending to a surface of the thin film transistor channel region, and a portion of an upper surface of the ohmic contact layer is covered by the passivation layer.

In one embodiment of the invention, the molybdenum ternary alloy barrier layer has a thickness of 0 to 1000 angstroms.

In one embodiment of the invention, the copper electrode layer has a thickness of 0 to 7000 angstroms.

In one embodiment of the invention, the thin film transistor array substrate further including a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure.

In one embodiment of the invention, the copper electrode layer is disposed on the molybdenum ternary alloy barrier layer.

The present invention further provides a thin film transistor array substrate including a substrate, a gate, a gate insulating layer, an active layer, an ohmic contact layer, a source/drain, a pixel electrode, and a passivation layer, which are sequentially disposed, wherein the gate and the source/drain are a two-layer structure including a molybdenum ternary alloy barrier layer and a copper electrode layer, wherein the molybdenum ternary alloy barrier layer includes three metal elements, two metal elements thereof are molybdenum and titanium, and the other metal element thereof is selected from one of aluminum, chromium, or nickel, wherein a projected area of the ohmic contact layer on the substrate is greater than or equal to a projected area of the source/drain on the substrate.

In one embodiment of the invention, a content of titanium ranges from 0.5% to 85%.

In one embodiment of the invention, a content of aluminum ranges from 0.5% to 85%, a content of chromium ranges from 0.5% to 85%, and a content of nickel ranges from 0.5% to 85%.

In one embodiment of the invention, the molybdenum ternary alloy barrier layer has a thickness of 0 to 1000 angstroms, wherein the copper electrode layer has a thickness of 0 to 7000 angstroms.

In one embodiment of the invention, the thin film transistor array substrate further including a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure. The copper electrode layer is disposed on the molybdenum ternary alloy barrier layer. The active layer further includes a thin film transistor channel region, the ohmic contact layer has a portion extending to a surface of the thin film transistor channel region, and a portion of an upper surface of the ohmic contact layer is covered by the passivation layer.

The present invention further provides a thin film transistor array substrate including a substrate, a gate, a gate insulating layer, an active layer, an ohmic contact layer, a source/drain, a pixel electrode, and a passivation layer, which are sequentially disposed, wherein the gate and the source/drain are a two-layer structure including a molybdenum ternary alloy barrier layer and a copper electrode layer. The molybdenum ternary alloy barrier layer includes three metal elements, two metal elements thereof are molybdenum and titanium, and the other metal element thereof is selected from one of aluminum, chromium, or nickel. The active layer further includes a thin film transistor channel region, the ohmic contact layer has a portion extending to a surface of the thin film transistor channel region, and a portion of an upper surface of the ohmic contact layer is covered by the passivation layer.

In one embodiment of the invention, a content of titanium ranges from 0.5% to 85%.

In one embodiment of the invention, a content of aluminum ranges from 0.5% to 85%, a content of chromium ranges from 0.5% to 85%, and a content of nickel ranges from 0.5% to 85%.

In one embodiment of the invention, the molybdenum ternary alloy barrier layer has a thickness of 0 to 1000 angstroms, wherein the copper electrode layer has a thickness of 0 to 7000 angstroms.

In one embodiment of the invention, the thin film transistor array substrate further including a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure. The copper electrode layer is disposed on the molybdenum ternary alloy barrier layer. A projected area of the ohmic contact layer on the substrate is greater than or equal to a projected area of the source/drain on the substrate.

### Beneficial Effect

The thin film transistor array substrate provided by the invention includes a molybdenum ternary alloy barrier layer, which not only has better corrosion resistance, but also has better etching characteristics; that is, while retaining the advantages of molybdenum, the probability of molybdenum being easily corroded in the photoresist stripping solution is reduced, thereby reducing undercut and tunneling of the metal layer in the thin film transistor array substrate.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural view of a thin film transistor array substrate according to a first embodiment of the present invention.

FIG. 2 is a schematic structural view of a thin film transistor array substrate according to a second embodiment of the present invention.

### DETAILED DESCRIPTION OF EMBODIMENTS

The following description of various embodiments is provided to illustrate the specific embodiments of the invention.

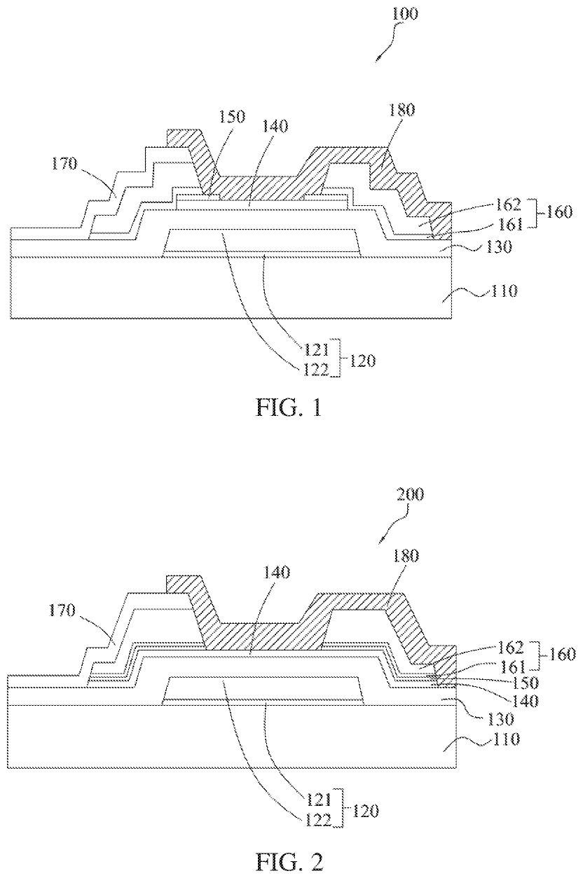

A thin film transistor array substrate provided by a first embodiment of the present invention, as shown in FIG. 1. The thin film transistor array substrate includes a substrate 110, a gate electrode 120, a gate insulating layer 130, an active layer 140, an ohmic contact layer 150, source/drain electrodes 160, a pixel electrode 170, and a passivation layer 180, wherein the gate electrode 120 and the source/drain electrodes 160 are of a two-layer structure including a molybdenum ternary alloy barrier layer 121/161 containing molybdenum (Mo) and a copper electrode layer 122/162. The thin film transistor array substrate of the present invention will be described in detail below by taking a thin film transistor structure 100 as an example.

As shown in FIG. 1, the specific structure of the thin film transistor array substrate includes the substrate 110; the gate electrode 120 disposed on the substrate 110; the gate electrode 120 having the two-layer structure including the molybdenum ternary alloy barrier layer 121 and the copper electrode layer 122, wherein the copper electrode layer 122 is disposed above the molybdenum ternary alloy barrier layer 121; the gate insulating layer 130 disposed on the gate electrode 120 and covering the gate electrode 120; the active layer 140 and the ohmic contact layer 150 disposed above the gate insulating layer 130 corresponding to the gate electrode 120, wherein the ohmic contact layer 150 is disposed above the active layer 140; the source/drain electrodes 160 disposed above the gate insulating layer 130 and connected to the ohmic contact layer 150, wherein the source/drain electrodes 160 are of the two-layer structure including the molybdenum ternary alloy barrier layer 161 containing molybdenum and the copper electrode layer 162, wherein the copper electrode layer 162 is disposed above the molybdenum ternary alloy barrier layer 161; the pixel electrode 170 disposed above the gate insulating layer 130 and connected to the source/drain electrodes 160; and the passivation layer 180 disposed above the source/drain electrodes 160, the active layer 140, and the ohmic contact layer 150, and covering a portion of the pixel electrode 170 positioned on the source/drain electrodes 160.

Meanwhile, the molybdenum ternary alloy barrier layer 121/161 of each of the gate electrodes 120 and the source/drain electrodes 160 includes three metal elements, wherein two metal elements are molybdenum and titanium (Ti), and the other metal element is selected from one of aluminum (Al), chromium (Cr), or nickel (Ni).

Optionally, molybdenum ternary alloy of each of the gate electrodes 120 and the source/drain electrodes 160 has a titanium content ranging from 0.5% to 85%.

Optionally, the molybdenum ternary alloy barrier layer includes a ternary alloy of molybdenum, titanium, and aluminum, wherein a content of aluminum ranges from 0.5% to 85%.

Optionally, the molybdenum ternary alloy barrier layer includes a ternary alloy of molybdenum, titanium, and chromium, wherein a content of chromium ranges from 0.5% to 85%.

Optionally, the molybdenum ternary alloy barrier layer includes a ternary alloy of molybdenum, titanium, and nickel, wherein a content of nickel ranges from 0.5% to 85%.

Alternatively, in the two-layer structure of each of the gate electrodes 120 and the source/drain electrodes 160, the molybdenum ternary alloy barrier layer 121/161 has a thickness of 0 to 1000 angstroms, and the copper electrode layer 122/162 has a thickness of 0 to 7000 angstroms.

A thin film transistor array substrate provided by a second embodiment of the present invention, as shown in FIG. 2. The thin film transistor array substrate includes a substrate 110, a gate electrode 120, a gate insulating layer 130, an active layer 140, an ohmic contact layer 150, source/drain electrodes 160, a pixel electrode 170, and a passivation layer 180, which are sequentially disposed; wherein the gate electrode 120 and the source/drain electrodes 160 are of a two-layer structure including a molybdenum ternary alloy barrier layer 121/161 and a copper electrode layer 122/162. Hereinafter, a thin film transistor structure 200 will be taken as an example, and the same portions as those of the first embodiment will not be repeatedly described, and only the differences will be described.

The difference between the second embodiment and the first embodiment is that sizes of the active layer 140 and the ohmic contact layer 150 in the second embodiment are greater; that is, contact areas between upper and lower surfaces of the active layer 140 and the ohmic contact layer 150 and the adjacent layers are increased, respectively. The size and area of the active layer 140 and the ohmic contact layer 150 are the same in design. A projected area of the ohmic contact layer 150 on the substrate 110 is greater than or equal to a projected area of the source/drain electrodes 160 on the substrate 110; that is, the source/drain electrodes 160 and the ohmic contact layer 150 have substantially the same size and area. As such, with respect to the structure of the first embodiment, a contact area of the source/drain electrodes 160 with the ohmic contact layer 150 in the second embodiment is greater than a contact area of the source/drain electrodes 160 and the ohmic contact layer 150 in the first embodiment.

Another difference is that the ohmic contact layer 150 of the second embodiment is substantially aligned with a boundary of the upper and lower layers at the end close to a channel of the thin film transistor. Since the ohmic contact layer 150 has a portion extending to a surface of a thin film transistor channel region in the first embodiment, and a portion of the upper surface of the ohmic contact layer 150 is covered by the passivation layer 180, with respect to the structure of the ohmic contact layer 150 in the second embodiment, a contact area of the ohmic contact layer 150 and the passivation layer 180 in the first embodiment is greater than a contact area of the ohmic contact layer 150 and the passivation layer 180 in the second embodiment.

As such, the difference in structure between the first embodiment and the second embodiment can provide different product requirements for thin film transistor functions.

In the above embodiments, taking the thin film transistor structures 100 and 200 as an example, during actual manufacturing process, a metal layer on the thin film transistor array substrate in addition to the above-mentioned gate electrode and source/drain electrodes, and gate electrodes, gate electrode pads, data lines, data pads, and other metal traces for electrical connection, which are sequentially disposed on the substrate, can all be arranged correspondingly with the two-layer structure in the above embodiments. Furthermore, the molybdenum ternary alloy barrier layer and the copper electrode layer are separately formed by a sputtering method.

The thin film transistor array substrate provided by the invention includes the molybdenum ternary alloy barrier layer, which not only has better corrosion resistance, but also has better etching characteristics; that is, while retaining the advantages of molybdenum, the probability of molybdenum being easily corroded in the photoresist stripping solution is reduced, thereby reducing undercut and tunneling of the metal layer in the thin film transistor array substrate. Moreover, the diffusion of copper from the copper electrode layer of the source/drain electrodes into the active layer can be further blocked by the molybdenum ternary alloy barrier layer of the source/drain electrodes.

Embodiments of the present invention have been described, but are not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A thin film transistor array substrate, comprising:
a substrate, a gate electrode, a gate insulating layer, an active layer, an ohmic contact layer, source/drain electrodes, a pixel electrode, and a passivation layer, which are sequentially disposed; wherein the gate electrode and the source/drain electrodes are a two-layer structure comprising a molybdenum ternary alloy barrier layer and a copper electrode layer.

2. The thin film transistor array substrate of claim 1, wherein the molybdenum ternary alloy barrier layer comprises three metal elements, two metal elements thereof are molybdenum and titanium, and the other metal element thereof is selected from one of aluminum, chromium, or nickel.

3. The thin film transistor array substrate of claim 2, wherein a content of titanium ranges from 0.5% to 85%.

4. The thin film transistor array substrate of claim 2, wherein a content of aluminum ranges from 0.5% to 85%, a content of chromium ranges from 0.5% to 85%, and a content of nickel ranges from 0.5% to 85%.

5. The thin film transistor array substrate of claim 1, wherein a projected area of the ohmic contact layer on the substrate is greater than or equal to a projected area of the source/drain electrodes on the substrate.

6. The thin film transistor array substrate of claim 1, wherein the active layer further comprises a thin film transistor channel region, the ohmic contact layer has a portion extending to a surface of the thin film transistor channel region, and a portion of an upper surface of the ohmic contact layer is covered by the passivation layer.

7. The thin film transistor array substrate of claim 2, wherein the molybdenum ternary alloy barrier layer has a thickness of 0 to 1000 angstroms.

8. The thin film transistor array substrate of claim 2, wherein the copper electrode layer has a thickness of 0 to 7000 angstroms.

9. The thin film transistor array substrate of claim 1, further comprising a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure.

10. The thin film transistor array substrate of claim 9, wherein the copper electrode layer is disposed on the molybdenum ternary alloy barrier layer.

11. A thin film transistor array substrate, comprising:
a substrate, a gate electrode, a gate insulating layer, an active layer, an ohmic contact layer, source/drain electrodes, a pixel electrode, and a passivation layer, which are sequentially disposed; wherein the gate electrode and the source/drain electrodes are a two-layer structure comprising a molybdenum ternary alloy barrier layer and a copper electrode layer;
wherein the molybdenum ternary alloy barrier layer comprises three metal elements, two metal elements thereof are molybdenum and titanium, and the other metal element thereof is selected from one of aluminum, chromium, or nickel;
wherein a projected area of the ohmic contact layer on the substrate is greater than or equal to a projected area of the source/drain electrodes on the substrate.

12. The thin film transistor array substrate of claim 11, wherein a content of titanium ranges from 0.5% to 85%.

13. The thin film transistor array substrate of claim 11, wherein a content of aluminum ranges from 0.5% to 85%, a content of chromium ranges from 0.5% to 85%, and a content of nickel ranges from 0.5% to 85%.

14. The thin film transistor array substrate of claim 11, wherein the molybdenum ternary alloy barrier layer has a thickness of 0 to 1000 angstroms, wherein the copper electrode layer has a thickness of 0 to 7000 angstroms.

15. The thin film transistor array substrate of claim 11, further comprising a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure;
wherein the copper electrode layer is disposed on the molybdenum ternary alloy barrier layer;
wherein the active layer further comprises a thin film transistor channel region, the ohmic contact layer has a portion extending to a surface of the thin film transistor channel region, and a portion of an upper surface of the ohmic contact layer is covered by the passivation layer.

16. A thin film transistor array substrate, comprising:
a substrate, a gate electrode, a gate insulating layer, an active layer, an ohmic contact layer, source/drain electrodes, a pixel electrode, and a passivation layer, which are sequentially disposed; wherein the gate electrode and the source/drain electrodes are a two-layer structure comprising a molybdenum ternary alloy barrier layer and a copper electrode layer;
wherein the molybdenum ternary alloy barrier layer comprises three metal elements, two metal elements thereof are molybdenum and titanium, and the other metal element thereof is selected from one of aluminum, chromium, or nickel;
wherein the active layer further comprises a thin film transistor channel region, the ohmic contact layer has a portion extending to a surface of the thin film transistor channel region, and a portion of an upper surface of the ohmic contact layer is covered by the passivation layer.

17. The thin film transistor array substrate of claim 16, wherein a content of titanium ranges from 0.5% to 85%.

18. The thin film transistor array substrate of claim 16, wherein a content of aluminum ranges from 0.5% to 85%, a content of chromium ranges from 0.5% to 85%, and a content of nickel ranges from 0.5% to 85%.

19. The thin film transistor array substrate of claim 16, wherein the molybdenum ternary alloy barrier layer has a thickness of 0 to 1000 angstroms, wherein the copper electrode layer has a thickness of 0 to 7000 angstroms.

20. The thin film transistor array substrate of claim 16, further comprising a plurality of gate electrodes, a plurality of gate electrode pads, a plurality of data lines, and a plurality of data pads sequentially disposed on the substrate, wherein the gate electrodes, the gate electrode pads, the data lines, and the data pads are the two-layer structure;
wherein the copper electrode layer is disposed on the molybdenum ternary alloy barrier layer;
wherein a projected area of the ohmic contact layer on the substrate is greater than or equal to a projected area of the source/drain electrodes on the substrate.
